(19) United States
(12) Patent Application Publication
(10) Pub. No.: US 2026/0164898 A1
(43) Pub. Date: Jun. 11, 2026

(54) DISPLAY DEVICE

(71) Applicant: LG Display Co., Ltd., Seoul (KR)

(72) Inventor: HyeongMin JEON, Goyang-si (KR)

(73) Assignee: LG Display Co., Ltd., Seoul (KR)

(21) Appl. No.: 19/336,005

(22) Filed: Sep. 22, 2025

(30) Foreign Application Priority Data
Dec. 9, 2024 (KR) 10-2024-0181553

(51) Int. Cl. H10H 29/853

(52) U.S. Cl. CPC H10H 29/853

(57) ABSTRACT

According to an aspect of the present disclosure, a display device includes a display panel having a plurality of rigid areas and a malleable area adjacent to the plurality of rigid areas, and a cover window on the display panel including a plurality of glass patterns and a resin layer covering one sides and side surfaces of the plurality of glass patterns. The plurality of glass patterns overlap the plurality of rigid areas, while the resin layer overlaps the malleable area. Accordingly, the glass patterns provide rigidity in the non-stretching regions, and the flexible resin layer enables stretching in the malleable area. This arrangement allows the display panel and the cover window to stretch together, maintaining structural stability while enabling mechanical flexibility.

### CROSS-REFERENCE TO RELATED APPLICATIONS

This application claims the priority benefit of Korean Patent Application No. 10-2024-0181553 filed on Dec. 9, 2024, in the Korean Intellectual Property Office, the disclosure of which is incorporated herein by reference.

### BACKGROUND

### Technical Field

The present disclosure relates to a display device, and more particularly to, for example, without limitation, a stretchable display device which can be stretched.

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Recently, a display device which is manufactured by forming a display unit and a wiring line on a flexible substrate such as plastic which is a flexible material so as to be stretchable in a specific direction and changed in various forms is getting attention as a next generation display device.

### BRIEF SUMMARY

The disclosed stretchable display device uses a hybrid cover window composed of rigid glass patterns combined with a flexible resin layer. The glass patterns overlap the rigid areas to provide optical clarity and mechanical strength, while the resin covers the malleable areas to allow the device to stretch without cracking or separation. The proportion of glass and resin can be adjusted according to material properties so that rigidity, flexibility, and adhesion can be balanced to meet different performance requirements.

The design also includes shaping of the glass patterns, such as reverse tapers, concave surfaces, and variable widths, to improve adhesion between the glass and resin, reduce stress concentrations, and limit cracking under repeated stretching. In certain forms, the resin layer functions both as a structural layer and as an adhesive, which reduces the total thickness of the device and simplifies the assembly process. A black resin layer with grooves may be added at the bezel area to conceal internal components while maintaining flexibility.

Control of material characteristics such as modulus, viscosity, and refractive index further enhances mechanical reliability, manufacturability, and optical performance. The use of temporary substrates, sacrificial layers, and laser assisted separation methods allows precise patterning of the glass patterns and clean integration with the display panel, resulting in a stretchable display device that combines durability, optical quality, and case of production.

For instance, various embodiments of the present disclosure provide a stretchable display device including a stretchable cover window.

Various embodiments of the present disclosure provide a stretchable display device including a cover window with improved appearance quality and rigidity.

Various embodiments of the present disclosure provide a stretchable display device including a cover window in which a ratio of a resin layer and a glass pattern varies in consideration of a material characteristic of the resin layer.

Various embodiments of the present disclosure provide a stretchable display device including a cover window with an improved adhesive strength between a plurality of glass patterns and a resin layer.

Various embodiments of the present disclosure provide a stretchable display device including a cover window in which a crack of a plurality of glass patterns is minimized or reduced during the stretching.

Still another object to be achieved by the present disclosure is to provide a stretchable display device including a cover window in which a black resin layer is formed in a bezel area.

Objects of the present disclosure are not limited to the above-mentioned objects, and other objects, which are not mentioned above, can be clearly understood by those skilled in the art from the following descriptions.

According to an aspect of the present disclosure, a display device includes a display panel which includes a plurality of rigid areas and a malleable area enclosing the plurality of rigid areas; and a cover window which is disposed on the display panel and includes a plurality of glass patterns and a resin layer which covers one sides and side surfaces of the plurality of glass patterns, in which the plurality of glass patterns overlaps the plurality of rigid areas and the resin layer overlaps the malleable area. Accordingly, the stretchable display device in which the glass pattern is disposed in the rigid area of the cover window which is not stretched and the flexible resin layer is disposed in the malleable area which is stretched so that the display panel and the cover window are stretched together may be provided.

Other detailed matters of the exemplary embodiments are included in the detailed description and the drawings.

According to the present disclosure, a cover window is formed with different types of materials to improve an appearance quality and a rigidity of the cover window.

According to the present disclosure, a ratio of the resin layer and the glass pattern varies according to a material of the resin layer to improve the rigidity and the durability of the cover window.

According to the present disclosure, a shape of the plurality of glass patterns is deformed to improve the adhesive strength between the plurality of glass patterns and the resin layer of the cover window.

According to the present disclosure, the crack of the plurality of glass patterns during the stretching may be minimized or reduced.

According to the present disclosure, a cover window in which a black resin layer is formed in the bezel area is disposed so that various components of the bezel area are not visible.

The effects according to the present disclosure are not limited to the contents exemplified above, and more various effects are included in the present specification.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic cross-sectional view of a display device according to an exemplary embodiment of the present disclosure;

FIG. 2 is a plan view of a display panel of a display device according to an exemplary embodiment of the present disclosure;

FIG. 3 is an enlarged plan view of a display device according to an exemplary embodiment of the present disclosure;

FIG. 4 is a schematic enlarged cross-sectional view of a display device taken along A-A′ of FIG. 3 according to an exemplary embodiment of the present disclosure;

FIGS. 5A to 5D are process diagrams for explaining a manufacturing method of a display device according to an exemplary embodiment of the present disclosure;

FIG. 6 is a schematic cross-sectional view of a display device according to another exemplary embodiment of the present disclosure;

FIG. 7 is a schematic enlarged cross-sectional view of a display device according to another exemplary embodiment of the present disclosure;

FIGS. 8A to 8D are process diagrams for explaining a manufacturing method of a display device according to another exemplary embodiment of the present disclosure;

FIG. 9 is a schematic enlarged plan view of a display device according to still another exemplary embodiment of the present disclosure;

FIG. 10 is a schematic enlarged cross-sectional view of a display device taken along B-B′ of FIG. 9 according to still another exemplary embodiment of the present disclosure;

FIG. 11 is a schematic enlarged plan view of a display device according to still another exemplary embodiment of the present disclosure;

FIG. 12 is a schematic enlarged cross-sectional view of a display device taken along C-C′ of FIG. 11 according to still another exemplary embodiment of the present disclosure;

FIGS. 13A to 13F are schematic enlarged cross-sectional views of a cover window according to various exemplary embodiments of the present disclosure;

FIG. 14 is a schematic plan view of a cover window of a display device according to still another exemplary embodiment of the present disclosure;

FIGS. 15A and 15B are schematic side views of a display device according to still another exemplary embodiment of the present disclosure;

FIG. 16 is a schematic rear view of a cover window of a display device according to still another exemplary embodiment of the present disclosure; and

FIGS. 17A and 17B are schematic right side views of a display device according to still another exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted or may be briefly discussed. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Any implementation described herein as an “example” is not necessarily to be construed as preferred or advantageous over other implementations.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

Also, when an element or layer is “connected,” “coupled,” or “adhered” to another element or layer denotes that the element or layer can not only be directly connected or adhered to another the other element or layer, but also be indirectly connected or adhered to another the other element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

The features of various embodiments of the present disclosure can be partially or entirely adhered to or combined with each other and can be interlocked and operated in technically various ways, and the embodiments can be carried out independently of or in association with each other.

Hereinafter, an exemplary embodiments of the present disclosure will be described in detail with reference to accompanying drawings.

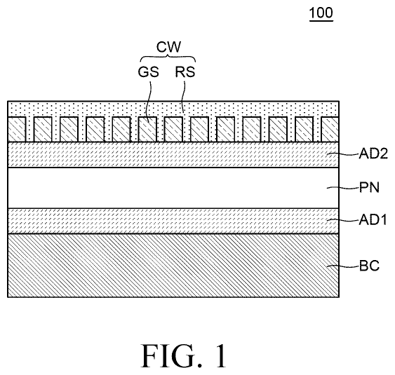

FIG. 1 is a schematic cross-sectional view of a display device according to an exemplary embodiment of the present disclosure.

First, a display device 100 according to an exemplary embodiment of the present disclosure is a display device 100 which is capable of displaying images even in a bent or extended state and may also be referred to as a stretchable display device, a flexible display device, an extendable display device, and the like. As compared with the general display devices of the related art, the display device 100 may have not only a high flexibility, but also stretchability. Therefore, the user may bend or extend a display device 100 and a shape of a display device 100 may be freely changed in accordance with manipulation of a user. For example, when the user pulls the display device 100 by holding ends of the display device, the display device 100 may be extended to the pulling direction of the user. Alternatively, when the user disposes the display device 100 on an outer surface which is not flat, the display device 100 may be disposed to be bent in accordance with the shape of the outer surface of the wall. Further, when a force applied by the user is removed, the display device 100 may return to its original shape.

Referring to FIG. 1, the display device 100 according to the exemplary embodiment of the present disclosure includes a stretchable display panel PN, a back cover BC, and a cover window CW.

The display panel PN is a configuration which displays an image and may be stretchably configured to be extended or bent. The display panel PN may include a lower substrate 111, a pattern layer 120, transistors 150 and 160, a light emitting diode 170, and an upper substrate 112 which are sequentially laminated. The light emitting diode 170 may emit light in response to the control of the transistors 150 and 160 so that an image may be displayed on a front surface of the display panel PN.

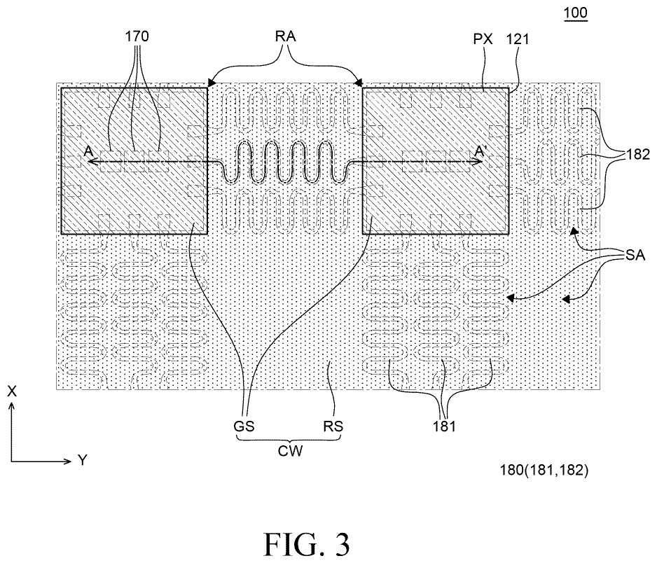

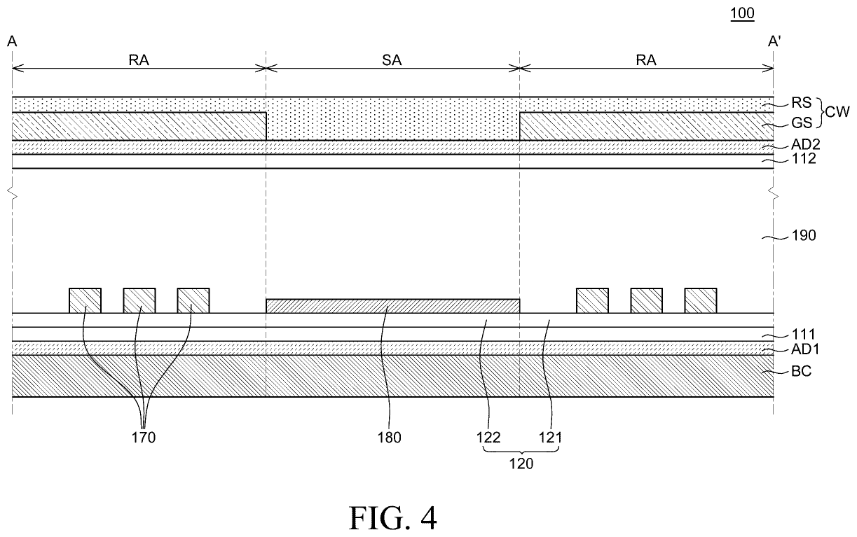

The cover window CW is disposed on the display panel PN. The cover window CW is a configuration for protecting a configuration below the cover window CW from shocks from the outside. The cover window CW may be configured to be stretchable, like the display panel PN. The cover window CW includes a plurality of glass patterns GS and a resin layer RS to be stretchable and will be described in more detail below with reference to FIGS. 3 and 4.

The back cover BC is disposed below the display panel PN. The back cover BC is a configuration which supplements the rigidity of the display panel PN and supports the display panel PN. The back cover BC may be configured to be stretchable, like the display panel PN. For example, the back cover BC may be formed of a stretchable insulating material, such as polydimethylsiloxane (PDMS).

A first adhesive layer AD1 may be disposed between the display panel PN and the back cover BC and a second adhesive layer AD2 may be disposed between the cover window CW and the display panel PN. The first adhesive layer AD1 and the second adhesive layer AD2 may bond the cover window CW, the display panel PN, and the back cover BC to each other. For example, the first adhesive layer AD1 and the second adhesive layer AD2 may be optically clear adhesives (OCA) and may be configured by an acrylic adhesive, a silicon-based adhesive, and an urethane-based adhesive.

In the meantime, the display device 100 may further include a touch unit which senses an input from the outside. The touch unit may be disposed above the display panel PN, below the display panel PN, or inside the display panel PN. For example, the touch unit may be disposed on a side of the display panel PN close to the upper substrate 112. The touch unit includes a plurality of touch electrodes to sense a change of mutual capacitance or self-capacitance and sense a touch input by a finger or a pen.

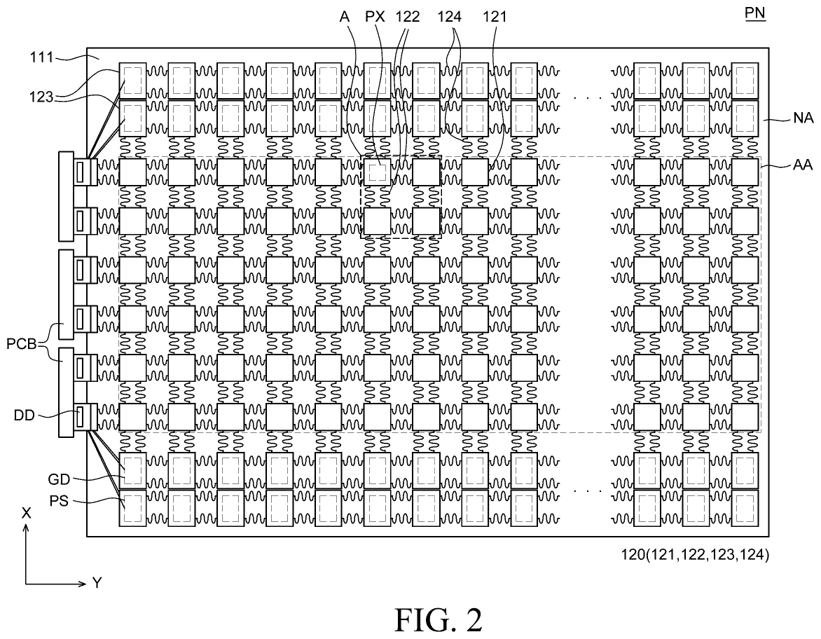

Hereinafter, a display panel PN of a display device 100 according to the exemplary embodiment of the present disclosure will be described in detail with reference to FIGS. 2 to 4.

FIG. 2 is a plan view of a display panel of a display device according to an exemplary embodiment of the present disclosure. FIG. 3 is an enlarged plan view of a display device according to an exemplary embodiment of the present disclosure. FIG. 4 is a schematic enlarged cross-sectional view of a display device taken along A-A′ of FIG. 3. For the convenience of description, in FIG. 2, the cover window CW is not illustrated and in FIG. 3, only a first plate pattern 121, a connection line 180, a light emitting diode 170, and a cover window CW are illustrated. Further, in FIG. 4, only a lower substrate 111, a pattern layer 120, a light emitting diode 170, a connection line 180, a filling layer 190, an upper substrate 112, a plurality of adhesive layers, a back cover BC, and a cover window CW of the display panel PN are illustrated.

Referring to FIGS. 2 to 4, the lower substrate 111 may support various components of the display panel PN and the upper substrate 112 may cover various components of the display panel PN.

The lower substrate 111 and the upper substrate 112 which are flexible substrates may be configured by an insulating material which is bendable or extendable. For example, the lower substrate 111 and the upper substrate 112 may be formed of a silicon rubber such as polydimethylsiloxane (PDMS) or an elastomer such as polyurethane (PU) or polytetrafluoroethylene (PTFE) and thus may have a flexibility. Further, the materials of the lower substrate 111 and the upper substrate 112 may be the same, but are not limited thereto and may vary.

The lower substrate 111 and the upper substrate 112 are flexible substrates so as to be reversibly expandable and contractible.

The display panel PN may have an active area AA in which images are displayed and a non-active area NA excluding the active area AA. The active area AA is an area where images are displayed in the display panel PN. In the active area AA, a plurality of pixels PX each including a display element and a circuit element may be disposed and in the non-active area NA, a gate driver GD and a power supply PS for driving the plurality of pixels PX disposed in the active area AA may be disposed.

The lower substrate 111 may also be defined to include a plurality of rigid areas RA and malleable areas SA. The rigid area RA may be referred to as a first area, and the malleable area SA may be referred to as a second area. The plurality of rigid areas RA may be disposed to be spaced apart from each other. The plurality of rigid areas RA may be areas of the lower substrate 111 overlapping the plurality of first plate patterns 121 and the plurality of second plate patterns 123. The plurality of rigid areas RA may be areas in which the plurality of first plate patterns 121 and the plurality of second plate patterns 123 are disposed to have a rigidity.

The malleable area SA may be an area which encloses each of the plurality of rigid areas RA. The malleable area SA may be an area which does not overlap the plurality of first plate patterns 121 and the plurality of second plate patterns 123. The malleable area SA is an area between the plurality of first plate patterns 121 and the plurality of second plate patterns 123 and may include an area in which the plurality of first line patterns 122 and the plurality of second line patterns 124 are disposed. Further, the malleable area SA may include an area in which the pattern layer 120 is not disposed. The malleable area SA may be an area in which the plurality of first plate patterns 121 and the plurality of second plate patterns 123 are not disposed to be flexibly deformable.

Accordingly, in the plurality of rigid areas RA, the plurality of first plate patterns 121 and the plurality of second plate patterns 123 are disposed and in the malleable area SA, the plurality of first plate patterns 121 and the plurality of second plate patterns 123 are not disposed so that the plurality of rigid areas RA may be more rigid than the malleable area SA.

At this time, the active area AA, the non-active area NA, the malleable area SA, and the plurality of rigid areas RA are not mentioned to be limited only to the display panel PN, but may be mentioned for the overall display device 100.

Next, the pattern layer 120 is disposed on the lower substrate 111. The pattern layer 120 may include a plurality of first plate patterns 121 and a plurality of first line patterns 122 disposed in the active area AA and a plurality of second plate patterns 123 and a plurality of second line patterns 124 disposed in the non-active area NA.

The plurality of first plate patterns 121 and the plurality of second plate patterns 123 may be substrates on which configurations, such as the pixel PX, the gate driver GD, and the power supply PS are formed. The plurality of first plate patterns 121 and the plurality of second plate patterns 123 may be disposed in the form of separate islands. The plurality of first plate patterns 121 and the plurality of second plate patterns 123 are spaced apart from each other to be disposed on the lower substrate 111. For example, the plurality of first plate patterns 121 and the plurality of second plate patterns 123 may be disposed in a matrix, but are not limited thereto. In the meantime, even though in FIG. 2, it is illustrated that the plurality of first plate patterns 121 and the plurality of second plate patterns 123 have a rectangular shape, the shape thereof is not limited thereto.

The plurality of first line patterns 122 may connect first plate patterns 121 which are adjacent to each other and the plurality of second line patterns 124 may connect a first plate pattern 121 and a second plate pattern 123 which are adjacent to each other or a plurality of second plate patterns 123 which is adjacent to each other. The plurality of first line patterns 122 and the plurality of second line patterns 124 may have a wavy shape, for example, a sine wave shape, but are not limited thereto.

The plurality of first plate patterns 121, the plurality of first line patterns 122, the plurality of second plate patterns 123, and the plurality of second line patterns 124 may be rigid patterns. For example, the plurality of first plate patterns 121, the plurality of first line patterns 122, the plurality of second plate patterns 123, and the plurality of second line patterns 124 may be more rigid than the lower substrate 111 and the upper substrate 112. Accordingly, moduli of elasticity and hardnesses of the plurality of first plate patterns 121, the plurality of first line patterns 122, the plurality of second plate patterns 123, and the plurality of second line patterns 124 may be higher than a modulus of elasticity and the hardness of the lower substrate 111. For example, moduli of elasticity of the plurality of first plate patterns 121, the plurality of first line patterns 122, the plurality of second plate patterns 123, and the plurality of second line patterns 124 may be 1000 times higher than the moduli of elasticity of the lower substrate 111 and the upper substrate 112, but it is not limited thereto.

The plurality of first plate patterns 121, the plurality of first line patterns 122, the plurality of second plate patterns 123, and the plurality of second line patterns 124 may be formed of a plastic material having a lower flexibility than the lower substrate 111 and the upper substrate 112.

Referring to FIGS. 2 and 3, a pixel PX including the plurality of sub pixels is disposed on the first plate pattern 121. For example, one pixel PX may include three sub pixels.

Each of the plurality of sub pixels may include a light emitting diode 170 and a circuit for driving the light emitting diode 170. The plurality of sub pixels may be connected to the plurality of connection lines 180. That is, the plurality of sub pixels may be electrically connected to a first connection line 181 extending in the first direction X and a second connection line 182 extending in the second direction Y.

Referring to FIG. 2, the gate driver GD may be mounted on the plurality of second plate patterns 123. The gate driver GD is a component which supplies a gate voltage to the plurality of pixels PX disposed in the active area AA. For example, the gate driver GD includes a plurality of stages formed on the plurality of second plate patterns 123 and each stage of the gate driver GD may be electrically connected to each other by means of the plurality of gate connection lines 180. Accordingly, a gate voltage output from any one of stages may be transmitted to the other stage. Each stage may sequentially supply the gate voltage to the plurality of pixels PX connected to each stage.

The power supply PS may be mounted in the plurality of second plate patterns 123. The power supply PS may be electrically connected to the gate driver GD and the plurality of pixels PX. For example, the power supply PS may supply a gate driving voltage and a gate clock voltage to the gate driver GD. The power supply PS is connected to the plurality of pixels PX to supply a pixel (PX) driving voltage to each of the plurality of pixels PX.

The printed circuit board PCB includes a controller, such as an IC chip or a circuit unit and/or a memory or a processor to transmit a signal and a voltage for driving the display element from the controller to the display element. The printed circuit board PCB may include a stretching area and a non-stretching area to ensure stretchability. For example, in the non-stretching area, an IC chip, a circuit unit, a memory, and a processor may be mounted and in the stretching area, wiring lines which are electrically connected to the IC chip, the circuit unit, the memory, and the processor may be disposed.

The data driver DD is a component which supplies a data voltage to the plurality of pixels PX disposed in the active area AA. The data driver DD may be configured as an IC chip so that it may also be referred to as a data integrated circuit D-IC.

A plurality of light emitting diodes 170 is disposed on the plurality of first plate patterns 121. The light emitting diode 170 may be any one of LED or a micro LED. However, an organic light emitting diode (OLED) may also be used as the light emitting diode 170, but is not limited thereto.

In the meantime, even though it is not illustrated in the drawing, a plurality of circuits and a plurality of wiring lines for driving the plurality of light emitting diodes 170 may be disposed together on the plurality of first plate patterns 121. For example, the plurality of circuits may include an element, such as a driving transistor, a switching transistor, and a storage capacitor. For example, the plurality of wiring lines may include a gate line, a data line, a high potential voltage line, a low potential voltage line, and a reference voltage line, depending on the configuration of the circuit.

The connection line 180 is disposed on the plurality of first line patterns 122. The connection line 180 refers to a wiring line which electrically connects pads on the plurality of first plate patterns 121. The connection line 180 is disposed on the plurality of first line patterns 122. The connection line 180 may extend onto the plurality of first plate patterns 121 from the plurality of first line patterns 122 to be electrically connected to the pads on the plurality of first plate patterns 121. The first line patterns 122 are not disposed in an area where the connection lines 180 are not disposed, among areas between the plurality of first plate patterns 121.

The connection line 180 includes a first connection line 181 and a second connection line 182. The first connection line 181 and the second connection line 182 are disposed between the plurality of first plate patterns 121. Specifically, the first connection line 181 refers to a wiring line extending in a first direction X between the plurality of first plate patterns 121, among the connection lines 180. The second connection line 182 refers to a wiring line extending in a second direction Y between the plurality of first plate patterns 121, among the connection lines 180. For example, the connection line 180 may include various metal materials.

In the case of a display panel of a general display device, various wiring lines such as a plurality of gate lines and a plurality of data lines extend between the plurality of sub pixels as a straight line shape and the plurality of sub pixels is connected to one signal line. Therefore, in the display panel of the general display device, various wiring lines, such as a gate line, a data line, a high potential voltage line, and a reference voltage line, extend from one side to the other side of the display panel without being disconnected on the substrate.

In contrast, in the display panel PN of the display device 100 according to the exemplary embodiment of the present disclosure, various wiring lines, such as a gate line, a data line, a high potential voltage line, a reference voltage line, and an initialization voltage line having a straight line shape which are considered to be used for the display panel PN of the general display device, are disposed only on the plurality of first plate patterns 121 and the plurality of second plate patterns 123.

In the display panel PN according to the exemplary embodiment of the present disclosure, the pads on two adjacent first plate patterns 121 may be connected by the connection lines 180. For example, the gate line may be disposed on the plurality of first plate patterns 121 disposed to be adjacent to each other in the first direction X and the gate pad may be disposed on both ends of the gate line. At this time, the plurality of gate pads on the plurality of first plate patterns 121 disposed adjacent to each other in the first direction X may be connected to each other by the first connection line 181. Therefore, the gate line disposed on the plurality of first plate patterns 121 and the first connection line 181 disposed on the first line pattern 122 may serve as one gate line.

Accordingly, among all various wiring lines which may be included in the display panel PN, wiring lines which extend in the first direction X, such as an emission signal line, a low potential voltage line, and a high potential voltage line, may also be electrically connected by the first connection line 181, as described above.

The second connection line 182 may connect pads on the plurality of first plate patterns 121 which is disposed to be adjacent to each other in the second direction Y. The second connection line 182 may connect pads of a data line, a high potential voltage line, a low potential voltage line, or a reference voltage line, but is not limited thereto.

The upper substrate 112 is a substrate which supports various components disposed below the upper substrate 112. Specifically, the upper substrate 112 is formed by coating a material which configures the upper substrate 112 on the lower substrate 111 and the first plate pattern 121 and then hardening the material.

In the meantime, even though in the drawing, it is illustrated that the upper substrate 112 is formed, the upper substrate 112 may be omitted depending on the design. In this case, the cover window CW disposed on the display panel PN may protect the configurations of the display panel PN, like the upper substrate 112.

The filling layer 190 is disposed between the upper substrate 112 and the lower substrate 111. The filling layer 190 is disposed on the entire surface of the lower substrate 111 to enclose the components disposed on the upper substrate 112 and the lower substrate 111. The filling layer 190 may be configured by a curable adhesive. Specifically, the material which configures the filling layer 190 is coated on the entire surface of the lower substrate 111 and then is hardened so that the filling layer 190 may be disposed between the configurations disposed on the upper substrate 112 and the lower substrate 111.

Referring to FIGS. 3 and 4, the cover window CW includes a plurality of glass patterns GS and a resin layer RS which encloses the plurality of glass patterns GS.

The plurality of glass patterns GS is rigid patterns formed of glass and may ensure the rigidity and the appearance quality of the cover window CW. The plurality of glass patterns GS is disposed in the plurality of rigid areas RA. The plurality of glass patterns GS may be disposed on the plurality of first plate patterns 121 on which the pixel PX is formed. The plurality of glass patterns GS may be disposed so as to overlap at least an area of the plurality of first plate patterns 121 in which the plurality of light emitting diodes 170 is disposed. A size of each of the plurality of glass patterns GS may be configured to be the same as the size of the first plate pattern 121.

The resin layer RS is a flexible pattern having elasticity and may ensure the stretchability of the cover window CW. The resin layer RS is disposed so as to enclose the plurality of glass patterns GS to fix the plurality of glass patterns GS. The resin layer RS may be disposed so as to cover side surfaces of the plurality of glass patterns GS and bottom surfaces of the plurality of glass patterns GS. In this case, a top surface of the cover window CW may be configured by top surfaces of the plurality of glass patterns GS and a top surface of the resin layer RS.

The cover window CW may be attached onto the upper substrate 112 of the display panel PN by means of the second adhesive layer AD2. The second adhesive layer AD2 is formed on the bottom surface of the cover window CW through which the plurality of glass patterns GS is exposed to bond the cover window CW and the display panel PN. The second adhesive layer AD2 may be in contact with the bottom surfaces of the plurality of glass patterns GS and the bottom surface of the resin layer RS.

The resin layer RS may be formed of a flexible material to be stretchable together with the display panel PN. For example, the resin layer RS may include a backbone material, such as silsesquioxane (SSQ) or siloxane-epoxy, and an elastomer such as rubber and a UV curing initiator. For example, the resin layer RS may have a room temperature hysteresis of approximately 1% or lower and an elastic recovery rate of approximately 80% or higher. Further, the stretching rate of the resin layer RS may be at least 8% or higher. The stretching rate of the resin layer RS may be approximately 20% or higher.

A modulus of the resin layer RS may have a value between 100 Mpa and 400 Mpa. If the modulus of the resin layer RS is lower than 100 Mpa, the hardness of the resin layer RS is low so that it is difficult to be used as the cover window CW and if the modulus of the resin layer RS is higher than 400 Mpa, the stretching rate of the resin layer RS is degraded so that it is difficult to form a flexible cover window CW.

A viscosity of the resin layer RS may have a value between approximately 800 cp and 3000 cp. If the viscosity of the resin layer RS is lower than 800 cp, it is difficult to control the flowability of the resin layer RS when the cover window CW is formed and if the viscosity of the resin layer RS is higher than 3000 cp, it is difficult to fill the resin layer RS in an area between the plurality of glass patterns GS.

A thickness of the resin layer RS located on the top surface of the plurality of glass patterns GS may have a value between 30 um and 80 um. If the thickness of the resin layer RS is smaller than 30 um, it is difficult to ensure the rigidity of the surface of the cover window CW and if the thickness of the resin layer RS is larger than 80 um, it is difficult to control curl when the cover window CW is formed.

The thickness of the plurality of glass patterns GS may have a value between approximately 50 μm and 330 um. If the thickness of the glass pattern GS is smaller than 50 um, it is difficult to ensure the rigidity of the cover window CW and if the thickness of the glass pattern GS is larger than 330 um, it is difficult to fill the resin layer RS in the area between the glass patterns GS and cracks may be easily caused during the Z-axis deformation.

A refractive index of the plurality of glass patterns GS is approximately 1.5 and a refractive index of the resin layer RS may have a value similar to the refractive index of the glass pattern GS, for example, a value between approximately 1.495 and 1.505. The total reflection caused by the difference in the refractive indices of the resin layer RS and the glass pattern GS may be suppressed by minimizing or reducing the difference in the refractive indices of the resin layer RS and the glass pattern GS.

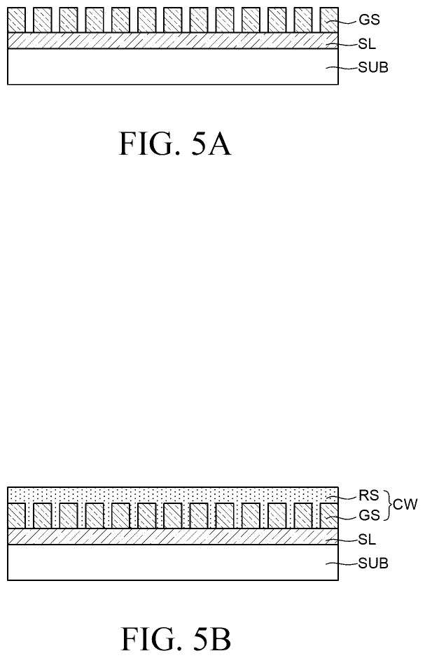

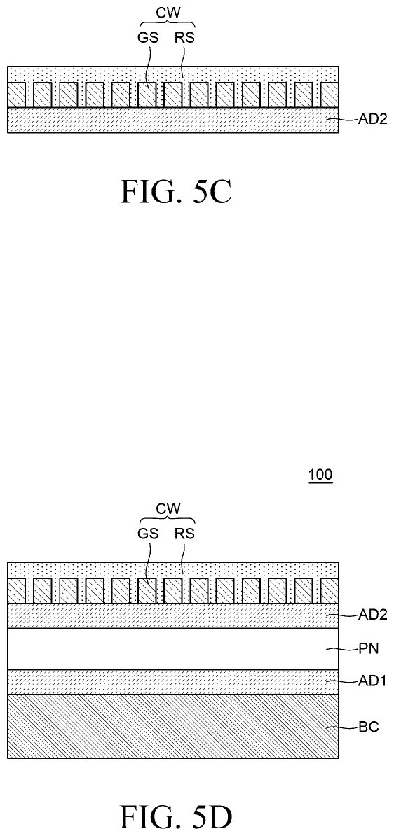

FIGS. 5A to 5D are process diagrams for explaining a manufacturing method of a display device according to an exemplary embodiment of the present disclosure.

Referring to FIG. 5A, a plurality of glass patterns GS is formed on a temporary substrate SUB. A glass layer is formed on the temporary substrate SUB on which a sacrificial layer SL is formed and is patterned into a plurality of pieces to form a plurality of glass patterns GS.

The temporary substrate SUB is a member which supports the cover window CW when the cover window CW is formed. The temporary substrate SUB may be formed of a material having a rigidity. For example, the temporary substrate SUB may be formed of glass, but is not limited thereto.

The sacrificial layer SL is a layer formed to easily separate the temporary substrate SUB and the cover window CW from each other. Laser is irradiated onto the sacrificial layer SL from the lower portion of the temporary substrate SUB to dehydrogenate the sacrificial layer SL and separate the temporary substrate SUB and the sacrificial layer SL from the cover window CW. For example, the sacrificial layer SL may use hydrogenated amorphous silicon or amorphous silicon which is hydrogenated and doped with impurities.

Next, referring to FIG. 5B, a resin layer RS which covers the plurality of glass patterns GS is formed. The resin layer RS is filled to the area between the plurality of glass patterns GS to be in contact with the top surfaces and the side surfaces of the plurality of glass patterns GS. Accordingly, the glass layer on the temporary substrate SUB is patterned to form the plurality of glass patterns GS and the resin layer RS is applied on the plurality of glass patterns GS to form the cover window CW.

Next, referring to FIG. 5C, the cover window CW and the temporary substrate SUB are separated and the second adhesive layer AD2 is formed on one surface of the cover window CW. The second adhesive layer AD2 may be formed on one surface of the cover window CW exposed from the temporary substrate SUB, that is, on the bottom surfaces of the plurality of glass patterns GS and the bottom surface of the resin layer RS.

Finally, referring to FIG. 5D, the cover window CW is attached onto the display panel PN using the second adhesive layer AD2. The cover window CW and the display panel PN may be bonded to each other by the second adhesive layer AD2.

Accordingly, in the display device 100 according to the exemplary embodiment of the present disclosure, the cover window CW is formed with different types of materials, that is, the plurality of glass patterns GS and the resin layer RS, to stretch the cover window CW together with the display panel PN. The plurality of glass patterns GS is disposed in the plurality of rigid areas RA and the resin layer RS is disposed in the malleable area SA to stretch the display panel PN and the cover window CW together. That is, the first plate pattern 121 of the display panel PN and the glass pattern GS of the cover window CW are disposed in the rigid area RA so as not to be stretched. The first line pattern 122 of the display panel PN and the resin layer RS of the cover window CW are disposed in the malleable area SA to be stretched together. If the glass pattern GS of the cover window CW is disposed in the malleable area SA, the stretching of the first line pattern 122 of the display panel PN may be interrupted by the glass pattern GS. Therefore, the rigid glass pattern GS is disposed in the rigid area RA and the malleable resin layer RS is disposed in the malleable area SA to stretch the display panel PN and the cover window CW together. In this case, a shear stress of the second adhesive layer AD2 disposed between the display panel PN and the cover window CW may be reduced so that the stress applied to the display panel PN may be reduced and a defect that the display panel PN and the cover window CW are separated may be minimized or reduced.

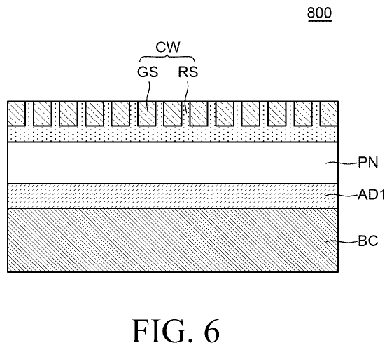

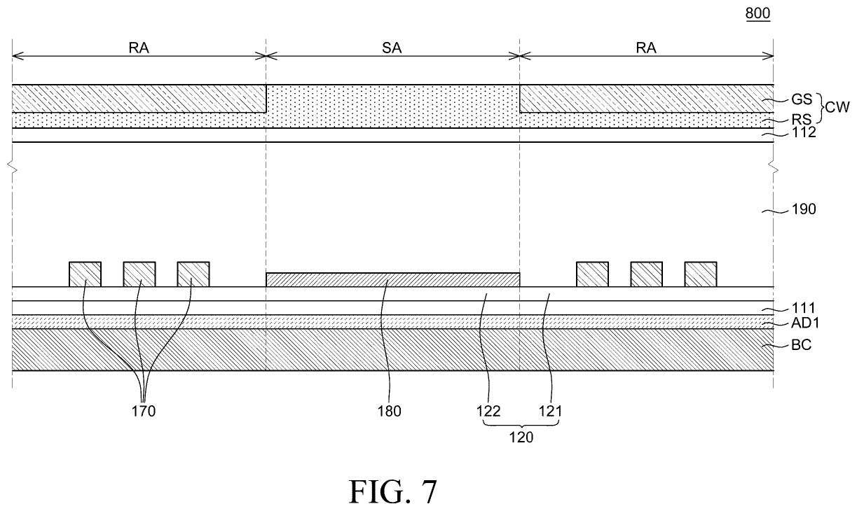

FIG. 6 is a schematic cross-sectional view of a display device according to another exemplary embodiment of the present disclosure. FIG. 7 is a schematic enlarged cross-sectional view of a display device according to another exemplary embodiment of the present disclosure. As compared with the display device 100 of FIGS. 1 to 4, in a display device 800 of FIGS. 6 and 7, a second adhesive layer AD2 is omitted and only a cover window CW is different, but the other configurations are substantially the same, so that a redundant description will be omitted.

Referring to FIGS. 6 and 7, the cover window CW is disposed on the display panel PN. The cover window CW includes a plurality of glass patterns GS and a resin layer RS which encloses the plurality of glass patterns GS.

The resin layer RS may cover side surfaces and bottom surfaces of the plurality of glass patterns GS. The resin layer RS may be disposed in an area between the plurality of glass patterns GS and the display panel PN and in an area between the plurality of glass patterns GS. A part of the resin layer RS (or a portion of the resin layer RS) disposed between the plurality of glass patterns GS and the display panel PN may serve as an adhesive layer which bonds the cover window CW and the display panel PN. Therefore, there is no need to form a separate adhesive layer between the cover window CW and the display panel PN so that the thickness of the display device 800 may be reduced.

At this time, top surfaces of the plurality of glass patterns GS may be exposed from the resin layer RS. A top surface of the cover window CW may be configured by the top surfaces of the plurality of glass patterns GS and a top surface of the resin layer RS.

The resin layer RS may be formed of a stretchable flexible material. For example, the resin layer RS may include a backbone material, such as silsesquioxane (SSQ) or siloxane-epoxy, and an elastomer such as rubber and a UV curing initiator. For example, the resin layer RS may have a room temperature hysteresis of approximately 1% or lower and an elastic recovery rate of approximately 80% or higher. Further, the stretching rate of the resin layer RS may be at least 8% or higher. The stretching rate of the resin layer RS may be approximately 20% or higher.

A modulus of the resin layer RS may have a value between approximately 0.1 Mpa and 10 Mpa. If the modulus of the resin layer RS is lower than 0.1 Mpa, the hardness of the resin layer RS is low so that it is difficult to improve the rigidity of the cover window CW. If the modulus of the resin layer RS is higher than 10 Mpa, the adhesive strength between the display panel PN and the resin layer RS is degraded so that it is difficult to bond the cover window CW and the display panel PN.

A viscosity of the resin layer RS may have a value between approximately 800 cp and 3000 cp. If the viscosity of the resin layer RS is lower than 800 cp, it is difficult to control the flowability of the resin layer RS when the cover window CW is formed and if the viscosity of the resin layer RS is higher than 3000 cp, it is difficult to fill the resin layer RS in an area between the plurality of glass patterns GS.

The thickness of the plurality of glass patterns GS may have a value between approximately 50 um and 330 um. If the thickness of the glass pattern GS is smaller than 50 um, it is difficult to ensure the rigidity of the cover window CW and if the thickness of the glass pattern GS is larger than 330 um, it is difficult to fill the resin layer RS in the area between the glass patterns GS and cracks may be easily caused during the Z-axis deformation.

A refractive index of the plurality of glass patterns GS is approximately 1.5 and a refractive index of the resin layer RS may have a value similar to the refractive index of the glass pattern GS, for example, a value between approximately 1.495 and 1.505. The total reflection caused by the difference in the refractive indices of the resin layer RS and the glass pattern GS may be suppressed by minimizing or reducing the difference in the refractive indices of the resin layer RS and the glass pattern GS.

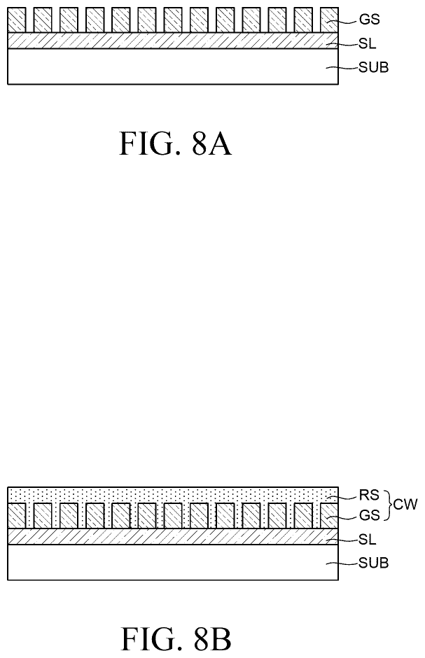

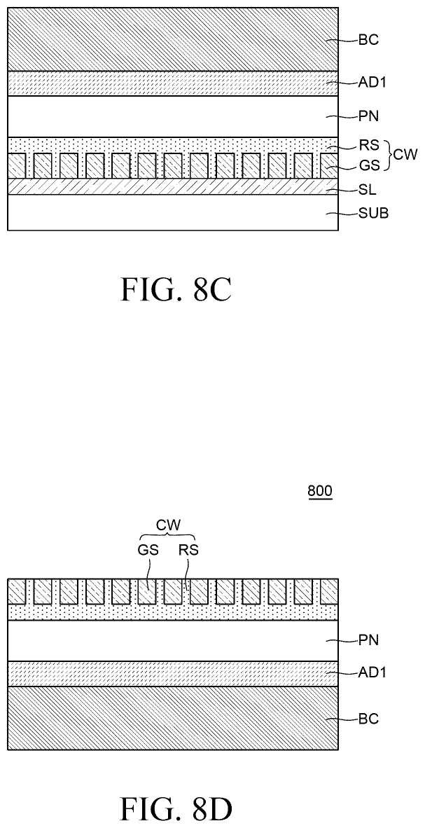

FIGS. 8A to 8D are process diagrams for explaining a manufacturing method of a display device according to another exemplary embodiment of the present disclosure.

Referring to FIG. 8A, a plurality of glass patterns GS is formed on a temporary substrate SUB. A glass layer is formed on the temporary substrate SUB and a sacrificial layer SL. The glass layer is patterned into a plurality of pieces to form a plurality of glass patterns GS.

Referring to FIG. 8B, a resin layer RS which covers the plurality of glass patterns GS is formed. The resin layer RS is filled to the area between the plurality of glass patterns GS to enclose one surfaces and the side surfaces of the plurality of glass patterns GS. Accordingly, the glass layer on the temporary substrate SUB is patterned to form the plurality of glass patterns GS and the resin layer RS is applied on the plurality of glass patterns GS to form the cover window CW.

Referring to FIG. 8C, the display panel PN is attached onto the resin layer RS. The cover window CW on the temporary substrate SUB and the display panel PN may be bonded to each other. In this case, the resin layer RS which is in contact with the display panel PN may serve as an adhesive layer which bonds the cover window CW and the display panel PN to each other.

Referring to FIG. 8D, the temporary substrate SUB is removed from the cover window CW. Accordingly, the temporary substrate SUB and the cover window CW are separated to form the display device 800 configured by the cover window CW, the display panel PN, the first adhesive layer AD1, and the back cover BC.

Accordingly, in the display device 800 according to another exemplary embodiment of the present disclosure, the cover window CW is configured by the plurality of glass patterns GS and the resin layer RS to form a stretchable cover window CW. At this time, the cover window CW may be formed using the temporary substrate SUB and the resin layer RS of the cover window CW may be directly bonded onto the display panel PN without a separate adhesive layer. Therefore, an adhesive layer for connecting the cover window CW and the display panel PN is omitted to simplify the structure of the display device 800.

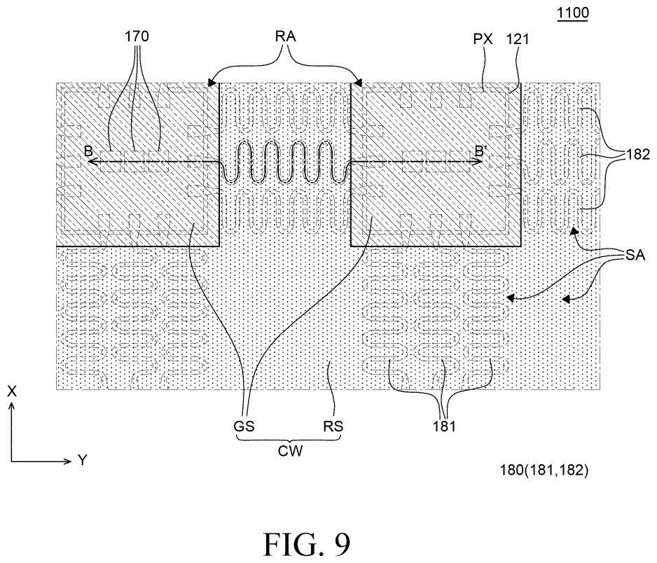

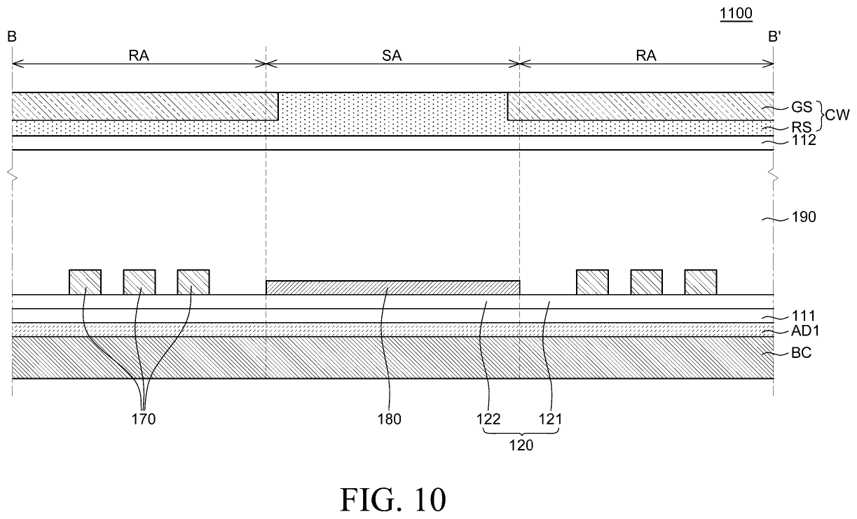

FIG. 9 is a schematic enlarged plan view of a display device according to still another exemplary embodiment of the present disclosure. FIG. 10 is a schematic enlarged cross-sectional view of a display device taken along B-B′ of FIG. 9. In a display device 1100 of FIGS. 9 and 10, only a glass pattern GS of the cover window CW is different from that of the display device 800 of FIGS. 6 and 7, but the other configurations are substantially the same so that a redundant description will be omitted.

Referring to FIGS. 9 and 10, each of the plurality of glass patterns GS may be formed to be larger than a size of the rigid area RA, that is, a size of the first plate pattern 121. At least a part of the glass pattern GS protrudes from the rigid area RA to be disposed on the malleable area SA. At least a part of the glass pattern GS may be disposed to extend from the rigid area RA to the malleable area SA. At least a part of the glass pattern GS may be disposed on the malleable area SA adjacent to an edge of the rigid area RA.

In the meantime, also in the display device 100 of FIGS. 1 to 4, a size of the plurality of glass patterns GS may be enlarged like the display device 1100 of FIGS. 9 and 10, but is not limited thereto.

Accordingly, in a display device 1100 according to still another exemplary embodiment of the present disclosure, a size of the plurality of glass patterns GS is formed to be larger than a size of the rigid area RA to increase a ratio of the plurality of glass patterns GS which occupies the cover window CW and reduce a ratio of the resin layer RS. The resin layer RS may be formed by selecting any one of various materials having stretchability. For example, when the resin layer RS is formed of a material which has a low rigidity due to the high stretching rate and has a relatively excellent adhesive strength with the plurality of glass patterns GS, among various materials, a ratio of the glass pattern GS which is a rigid pattern is increased and a ratio of the resin layer RS is lowered. By doing this, the rigidity of the cover window CW may be ensured to be a predetermined level or higher. Further, the resin layer RS is formed with a material having excellent adhesive strength with the glass pattern GS so that even though the ratio of the resin layer RS is reduced, the resin layer RS may easily fix the plurality of glass patterns GS. Accordingly, the ratio of the resin layer RS and the plurality of glass patterns GS varies in consideration of the characteristic of the resin layer RS to improve the rigidity and the durability of the cover window CW.

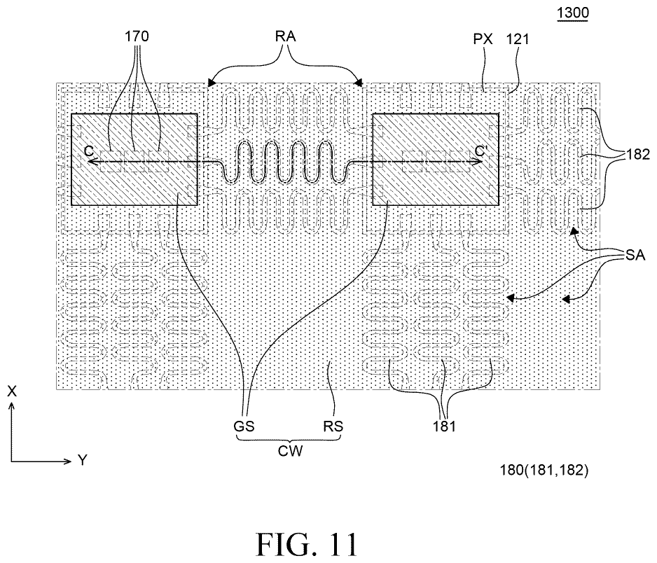

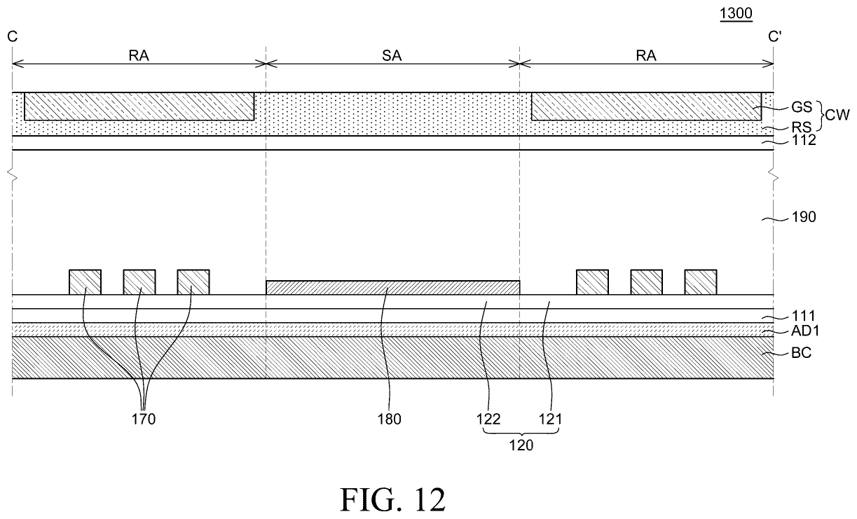

FIG. 11 is a schematic enlarged plan view of a display device according to still another exemplary embodiment of the present disclosure. FIG. 12 is a schematic enlarged cross-sectional view of a display device taken along C-C′ of FIG. 11. In a display device 1300 of FIGS. 11 and 12, only a glass pattern GS of the cover window CW is different from that of the display device 800 of FIGS. 6 and 7, but the other configurations are substantially the same so that a redundant description will be omitted.

Referring to FIGS. 11 and 12, each of the plurality of glass patterns GS may be formed to be smaller than a size of the rigid area RA, that is, a size of the first plate pattern 121. At least a part of the resin layer RS may be disposed to extend from the malleable area SA to the rigid area RA. The size of the glass pattern GS may be formed in the range between a size which covers all the plurality of light emitting diodes 170 disposed on one first plate pattern 121 and a size of the first plate pattern 121.

At this time, a boundary of the glass pattern GS and the resin layer RS may not overlap the plurality of light emitting diodes 170. An edge of the glass pattern GS may overlap an area outside the light emitting diode 170. If an interface of the glass pattern GS and the resin layer RS overlaps the light emitting diode 170, the interface of the glass pattern GS and the resin layer RS having a difference in refractive index may be visible. Accordingly, the glass pattern GS is formed to be larger than an area of the rigid area RA in which at least the plurality of light emitting diodes 170 is disposed to cover the plurality of light emitting diodes 170.

In the meantime, also in the display device 100 of FIGS. 1 to 4, a size of the plurality of glass patterns GS may be reduced like the display device 1300 of FIGS. 11 and 12, but is not limited thereto.

Accordingly, in a display device 1300 according to still another exemplary embodiment of the present disclosure, a size of the plurality of glass patterns GS is formed to be smaller than a size of the rigid area RA to reduce a ratio of the plurality of glass patterns GS which occupies the cover window CW and increase a ratio of the resin layer RS. The resin layer RS may be formed by selecting any one of various materials having stretchability. For example, when the resin layer RS is formed of a material which has a high rigidity due to the low stretching rate and has a relatively low adhesive strength with the plurality of glass patterns GS, among various materials, even though a ratio of the glass pattern GS is reduced somewhat, the rigidity of the cover window CW may be ensured to be a predetermined level or higher. Further, the resin layer RS is formed with a material having relatively low adhesive strength with the glass pattern GS so that the ratio of the resin layer RS is increased to supplement the low adhesive strength between the resin layer RS and the plurality of glass patterns GS. Accordingly, a ratio of the resin layer RS and the plurality of glass patterns GS may vary in consideration of the characteristic of the resin layer RS.

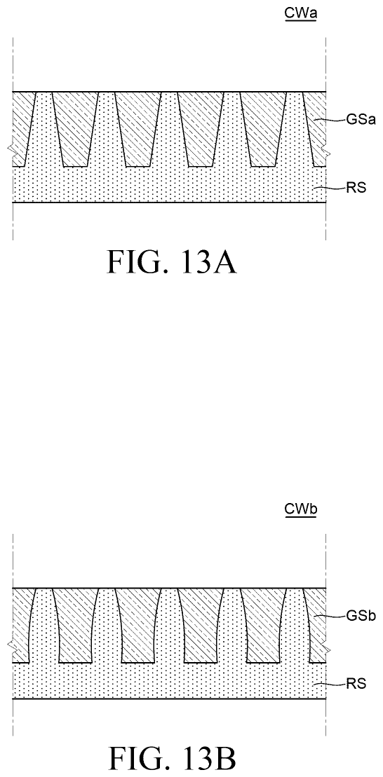

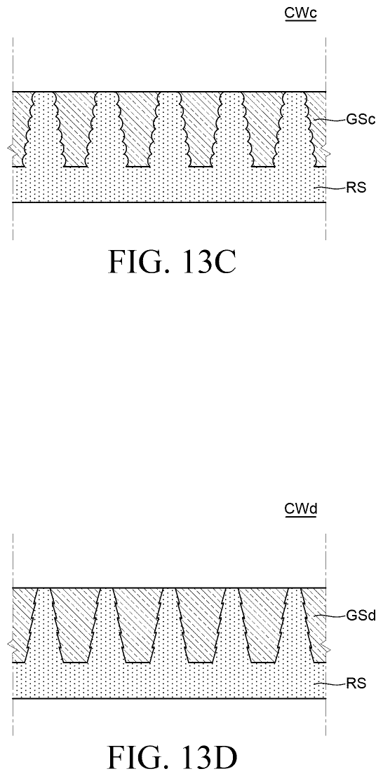

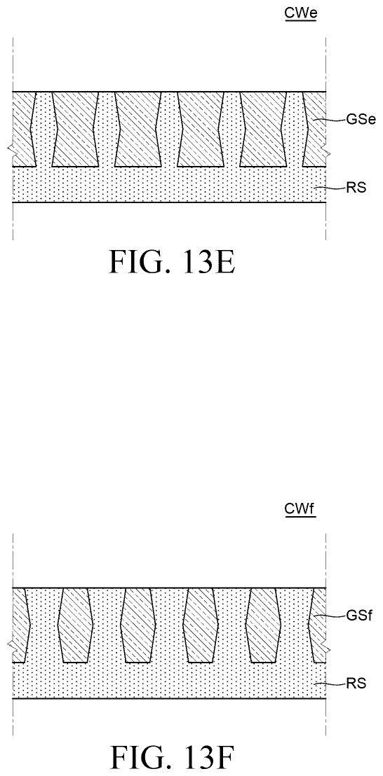

FIGS. 13A to 13F are schematic enlarged cross-sectional views of a cover window according to various exemplary embodiments of the present disclosure.

Referring to FIGS. 13A to 13F, the plurality of glass patterns GS of the cover window CW may be formed with various shapes. The plurality of glass patterns GS of the cover window may be formed with various shapes to improve the adhesive strength between the plurality of glass patterns GS and the resin layer RS and minimize or reduce the crack of the plurality of glass patterns GS.

Referring to FIG. 13A, a first cover window CWa includes a plurality of first glass patterns GSa and a resin layer RS. The first glass pattern GSa may be formed to be narrowed toward an opposite surface of one surface from one surface. For example, the first glass pattern GSa may be formed with a reverse taper shape which is narrowed toward the bottom surface from the top surface. A side surface of each of the plurality of first glass patterns GSa may be slantly formed. The first glass pattern GSa may have a shape which is narrowed toward the bottom surface of the first glass pattern GSa from the top surface. The laser is irradiated from the bottom of the first glass pattern GSa to the first glass pattern GSa to form the first glass pattern GSa with a reverse taper shape. Accordingly, a ratio of the first glass pattern GSa which occupies a surface of the first cover window CWa may be increased and the rigidity of the surface of the first cover window CWa may be maximized or improved.

However, the first glass pattern GSa may have a shape which is narrowed from the bottom surface to the top surface, that is, a taper shape which is widened from the top surface to the bottom surface, but is not limited thereto.

Referring to FIG. 13B, a second cover window CWb includes a plurality of second glass patterns GSb and a resin layer RS. The plurality of second glass patterns GSb may be formed with a reverse taper shape, like the plurality of first glass patterns GSa. At this time, the side surface of the second glass pattern GSb may be formed to have a concave curved surface. Accordingly, a ratio of the second glass pattern GSb which occupies a surface of the second cover window CWb may be increased and the rigidity of the surface of the second cover window CWb may be maximized or improved. Further, the side surface of the second glass pattern GSb is formed to be concave so that a contact area of the second glass pattern GSb and the resin layer RS may be increased and the ratio of the resin layer RS in the entire second cover window CWb may be increased.

Referring to FIG. 13C, a third cover window CWc includes a plurality of third glass patterns GSc and a resin layer RS. The plurality of third glass patterns GSc may be formed to have a reverse taper shape. At this time, side surfaces of the plurality of third glass patterns GSc may be uneven surfaces including a plurality of irregularities. For example, a plurality of concave portions is formed on side surfaces of the plurality of third glass patterns GSc to form an uneven surface.

As used herein, the term “irregularities” refers to surface features that deviate from a flat or smooth surface and include, for example, projections, recesses, ridges, grooves, or combinations thereof formed on the surface of the glass pattern. The irregularities may have varying shapes such as linear, curved, polygonal, or random geometries and may be periodic or non-periodic. In some embodiments, the irregularities have a height or depth measured from an adjacent flat portion of the surface, and a width or spacing between adjacent irregularities, which may be defined in micrometers or other units. The irregularities may be provided to improve adhesion between the resin layer and the glass pattern or to control mechanical deformation characteristics of the cover window.

Referring to FIG. 13D, a fourth cover window CWd includes a plurality of fourth glass patterns GSd and a resin layer RS. The plurality of fourth glass patterns GSd may be formed to have a reverse taper shape. The plurality of fourth glass patterns GSd may be formed of an uneven surface due to irregularities formed on the side surfaces. For example, the side surfaces of the plurality of fourth glass patterns GSd may be formed to have a sawtooth shape.

Referring to FIGS. 13C and 13D together, the irregular surfaces of the plurality of third glass patterns GSc and the plurality of fourth glass patterns GSd may be formed by irradiating laser or performing dry-etching. Accordingly, in the plurality of third glass patterns GSc and the plurality of fourth glass patterns GSd, a contact area of the resin layer RS is increased by the irregular surface to improve the adhesive strength with the resin layer RS. Further, when the third cover window CWc and the fourth cover window CWd are stretched, the separation of the plurality of third glass patterns GSc and the plurality of fourth glass patterns GSd from the resin layer RS is minimized or reduced, which improves the reliability of the third cover window CWc and the fourth cover window CWd.

Referring to FIG. 13E, a fifth cover window CWe includes a plurality of fifth glass patterns GSe and a resin layer RS. The plurality of fifth glass patterns GSe may have a shape which is the widest on the top surface and the bottom surface and is the narrowest in the center. The plurality of fifth glass patterns GSe may have a shape which is narrowed from the top surface to the center and is widened from the center to the bottom surface.

Referring to FIG. 13F, a sixth cover window CWf includes a plurality of sixth glass patterns GSf and a resin layer RS. The plurality of sixth glass patterns GSf may have a shape which is the widest in the center and is the narrowest on the top surface and the bottom surface. The plurality of sixth glass patterns GSf may have a shape which is widened from the top surface to the center and is narrowed from the center to the bottom surface.

Referring to FIGS. 13E and 13F together, in the plurality of fifth glass patterns GSe and the plurality of sixth glass patterns GSf, widths in the center portion and the upper portion and the lower portion are configured to be different so that the crack due to the Z-axis deformation or the separation from the resin layer RS may be minimized or reduced. For example, when the fifth cover window CWe and the sixth cover window CWf are deformed in the Z-axis direction, stress applied to the plurality of fifth glass patterns GSe and the plurality of sixth glass patterns GSf is dispersed to minimize or reduce the crack of the plurality of fifth glass patterns GSe and the plurality of sixth glass patterns GSf. Further, the separation of the fifth glass patterns GSe and the sixth glass patterns GSf from the resin layer RS may be minimized or reduced.

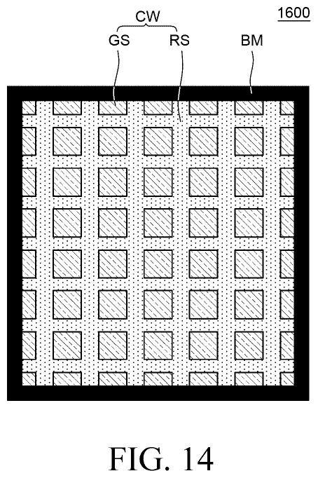

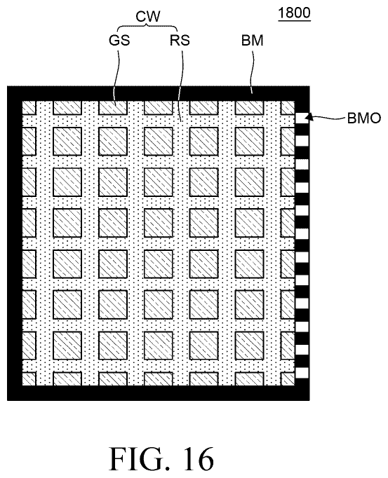

In the meantime, the plurality of glass patterns GSa, GSb, GSc, GSd, GSe, and GSf of FIGS. 13A to 13F may be applied to all the display device 100 of FIGS. 1 to 4, the display device 800 of FIGS. 6 and 7, the display device 1100 of FIGS. 9 and 10, the display device 1300 of FIGS. 11 and 12, a display device 1600 of FIG. 14 and a display device 1800 of FIG. 16 to be described below.

Accordingly, in the cover windows CWa, CWb, CWc, CWd, CWe, and CWf according to various exemplary embodiments of the present disclosure, the plurality of glass patterns GSa, GSb, GSc, GSd, GSe, and GSf is formed with various structures to improve the appearance quality and the reliability of the cover windows CWa, CWb, CWc, CWd, CWe, and CWf. For example, the glass patterns GSa, GSb, GSc, GSd, GSe, and GSf are formed to have a reverse taper shape to improve the appearance quality. Further, the side surfaces of the glass patterns GSa, GSb, GSc, GSd, GSe, and GSf are formed as curved surfaces or irregular surfaces to improve the adhesive strength between the glass patterns GSa, GSb, GSc, GSd, GSe, and GSf and the resin layer RS. Further, widths of the glass patterns GSa, GSb, GSc, GSd, GSe, and GSf vary to suppress the cracks of the glass patterns GSa, GSb, GSc, GSd, GSc, and GSf and improve the adhesive strength between the glass patterns GSa, GSb, GSc, GSd, GSe, and GSf and the resin layer RS.

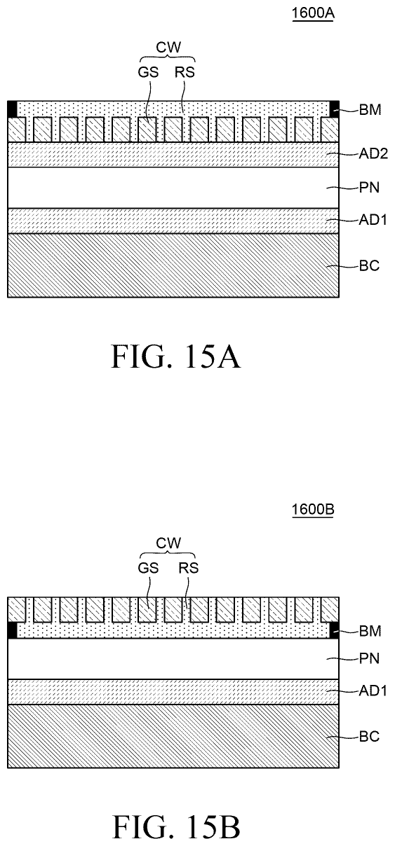

FIG. 14 is a schematic plan view of a cover window of a display device according to still another exemplary embodiment of the present disclosure. FIGS. 15A and 15B are schematic side views of a display device according to still another exemplary embodiment of the present disclosure. As compared with the display device 100 of FIGS. 1 to 4 and the display device 800 of FIGS. 6 and 7, a display device 1600 of FIG. 14 further includes a black resin layer BM, but the other configuration is substantially the same so that a redundant description will be omitted.

Referring to FIG. 14, the display device 1600 according to still another exemplary embodiment of the present disclosure further includes a black resin layer BM. The black resin layer BM is disposed in an edge of the cover window CW to block various components disposed in the bezel of the display device 1600 so as not to be visible. The black resin layer BM may be disposed on the same plane as a part of the resin layer RS which covers one surface of the plurality of glass patterns GS. The black resin layer BM may be disposed so as to enclose the resin layer RS and may be in contact with a side surface of the resin layer RS. The black resin layer BM may be in contact with one surface of a glass pattern GS disposed at the outermost side, among the plurality of glass patterns GS.

Referring to FIG. 15A, in the display device 1600A in which the resin layer RS covers the top surface of the plurality of glass patterns GS so that the surface of the cover window CW is configured by the resin layer RS. The black resin layer BM may be disposed along the edge of the cover window CW on the top surface of the cover window CW. The black resin layer BM may be disposed so as to cover the top surfaces of the plurality of glass patterns GS together with the resin layer RS.

Referring to FIG. 15B, in the display device 1600B in which the resin layer RS covers the bottom surface of the plurality of glass patterns GS so that the surface of the cover window CW is configured by the resin layer RS and the plurality of glass patterns GS. The black resin layer BM may be disposed along the edge of the cover window CW on the bottom surface of the cover window CW. The black resin layer BM may be disposed so as to cover the bottom surfaces of the plurality of glass patterns GS together with the resin layer RS.

The black resin layer BM may be formed by adding a black material, for example, carbon black or carbon nano tube to the same material as the resin layer RS. An optical density (OD) of the black resin layer BM may be 1 or larger. When the resin layer RS is formed on the plurality of glass patterns GS, the resin which forms the black resin layer BM is applied together to form the black resin layer BM.

Accordingly, in the display device 1600 according to still another exemplary embodiment of the present disclosure, the black resin layer BM is formed in the edge of the cover window CW so that various components of the bezel are not visible. The resin layer RS and the black resin layer BM which encloses the resin layer RS are formed on one surface of the plurality of glass patterns GS to form a black bezel and there is no need to form a separate black layer so that the structure of the display device 1600 may be simplified.

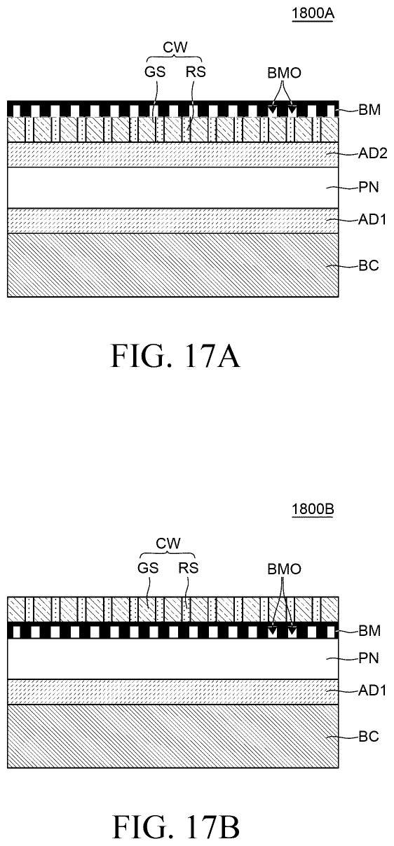

FIG. 16 is a schematic rear view of a cover window of a display device according to still another exemplary embodiment of the present disclosure. FIGS. 17A and 17B are schematic right side views of a display device according to still another exemplary embodiment of the present disclosure. As compared with the display device 1600 of FIG. 14, except that in a display device 1800 of FIG. 16, a black resin layer BM further includes a plurality of grooves BMO, the other configuration is substantially the same, so that a redundant description will be omitted. In FIG. 16, for the convenience of description, hatching is added only to an area in which the plurality of grooves BMO is not formed and hatching is removed from the area in which the plurality of grooves BMO is formed to distinguish the area in which the plurality of grooves BMO is disposed.

Referring to FIG. 16, the black resin layer BM includes a plurality of grooves BMO formed on the bottom surface of the black resin layer BM. The plurality of grooves BMO may be formed in at least a part of the black resin layer BM. For example, even though in FIG. 16, it is illustrated that the plurality of grooves BMO is formed only in one side, among four sides of the cover window CW, but is not limited thereto.

The plurality of grooves BMO may extend from the bottom surface to the top surface of the black resin layer BM. The plurality of grooves BMO does not completely pass through the black resin layer BM, but may be formed only in a part of the black resin layer BM. The plurality of grooves BMO of the black resin layer BM may not be visible from the surface of the cover window CW. However, the plurality of grooves BMO of the black resin layer BM may be visible from the side surface of the cover window CW.

A thickness of the black resin layer BM which overlaps the plurality of grooves BMO may be smaller than a thickness of the remaining part which does not overlap the plurality of grooves BMO. The plurality of grooves BMO is formed so that a part of the black resin layer BM has a relatively small thickness. Therefore, the black resin layer BM may be more flexibly deformed.

Referring to FIG. 17A, in the case of a display device 1800A in which the black resin layer BM is configured to cover the top surfaces of the plurality of glass patterns GS, a plurality of grooves BMO may be formed from the bottom surface to the top surface of the black resin layer BM. In an area in which the plurality of grooves BMO is formed, a gap may be formed between the black resin layer BM and the top surface of the glass pattern GS and between the other part of the resin layer RS filled between the plurality of glass patterns GS and the black resin layer BM.

Referring to FIG. 17B, in the case of a display device 1800B in which the black resin layer BM is configured to cover the bottom surfaces of the plurality of glass patterns GS, a plurality of grooves BMO may be formed from the bottom surface to the top surface of the black resin layer BM. In an area in which the plurality of grooves BMO is formed, a gap may be formed between the black resin layer BM and the top surface of the display panel PN.

Accordingly, in the display device 1800 according to still another exemplary embodiment of the present disclosure, a plurality of grooves BMO is formed on the bottom surface of the black resin layer BM to increase the stretching rate of the black resin layer BM. The plurality of grooves BMO is formed in the black resin layer BM so that the black resin layer BM having a small thickness in the groove BMO may be more flexibly deformed. Accordingly, the plurality of grooves BMO is formed in the black resin layer BM to improve the stretching rate of the black resin layer BM and the black resin layer BM, the cover window CW, and the display panel PN may be easily stretched.

The exemplary embodiments of the present disclosure can also be described as follows:

A display device may include a first substrate 111 having a first area RA and a second area SA adjacent to the first area RA. The first area RA may have a higher modulus of elasticity than the second area SA (namely, the first area is stiffer and less likely to deform under stress and the second area is more flexible or “malleable”, meaning it can bend or stretch more easily when the device flexes). A cover window CW may be disposed on the first substrate 111 and may include a glass pattern GS having at least one surface and a resin layer RS adjacent to the at least one surface of the glass pattern GS. In some embodiments, the glass pattern may overlap the first area and the resin layer may overlap the second area when viewed in plan view.

In certain embodiments, the resin layer may be in direct contact with the at least one surface of the glass pattern. The direct contact between the resin layer and the glass pattern may enhance structural integrity and adhesion between the components while minimizing the need for intermediate bonding materials.

In some embodiments, the resin layer may further overlap the first area in plan view. The extension of the resin layer into portions of the first area may provide additional structural reinforcement or optical control depending on the material properties of the resin layer.

In other embodiments, the glass pattern may further overlap the second area SA in plan view (see FIG. 10). The extension of the glass pattern into portions of the second area may facilitate planarization or optical uniformity across boundaries between the first and second areas.

In some embodiments, the first area may include a light emitting diode 170. A filling layer 190 may be disposed on the light emitting diode, and a second substrate 112 may be disposed on the filling layer 190. In these embodiments, the glass pattern GS may overlap the light emitting diode 170 in plan view, providing mechanical protection and optical transparency above the active device region.

In certain embodiments, an adhesive layer AD2 may be disposed on the second substrate 112 (see FIG. 4). The adhesive layer AD2 may be in direct contact with both the glass pattern GS and the resin layer RS, thereby bonding the cover window assembly to the underlying substrate layers.

In other embodiments, the resin layer may be in direct contact with the second substrate 112 (see FIG. 7). The direct contact between the resin layer RS and the second substrate 112 may be provided in the absence of any intermediate bonding layers, thereby reducing thickness and simplifying manufacturing processes.

In some embodiments, the resin layer may have greater thickness above the second area than above the first area. The increased thickness above the second area may improve flexibility and stretchability where required by the design of the display panel.

In certain embodiments, the glass pattern and the resin layer may together form a planar continuous outermost surface. The planarization provided by the resin layer in combination with the glass pattern may enhance optical uniformity and provide a smooth tactile surface for user interaction.

In some embodiments, the resin layer may contact both the second substrate and the glass pattern without an intermediate adhesive layer (see FIGS. 10 and 12). The elimination of intermediate adhesives may reduce optical distortion and simplify the assembly process while maintaining structural integrity.

In some embodiments, a black resin layer BM different from the resin layer RS may be disposed along an edge of the cover window. The black resin layer BM may surround the resin layer in plan view, providing an optical border or masking region around the periphery of the display panel.

In certain embodiments the black resin layer BM may include grooves BMO defined along at least one edge of the cover window. The grooves may reduce mechanical stress concentrations and improve flexibility along the periphery of the cover window.

In some embodiments, the glass pattern may have surfaces including alternating tapered and reverse tapered portions in cross-sectional view. The alternating tapered geometries may improve adhesion between the resin layer and the glass pattern while enhancing mechanical robustness.

In other embodiments, the glass pattern may have surfaces shaped with a concave curvature extending toward the resin layer. The concave curvature may increase the contact area between the glass pattern and the resin layer to improve bonding strength.

In some embodiments, the glass pattern may have surfaces including irregular projections extending into the resin layer. The irregular projections may mechanically interlock with the resin layer to enhance adhesion and resist delamination under mechanical stress.

The exemplary embodiments of the present disclosure can further be described as follows:

According to an aspect of the present disclosure, a display device includes a display panel which includes a plurality of rigid areas and a malleable area enclosing the plurality of rigid areas, and a cover window which is disposed on the display panel and includes a plurality of glass patterns and a resin layer which covers one sides and side surfaces of the plurality of glass patterns, and the plurality of glass patterns overlaps the plurality of rigid areas and the resin layer overlaps the malleable area.

The display panel may further include a plurality of light emitting diodes each disposed in each of the plurality of rigid areas and each of the plurality of glass patterns may overlap the plurality of light emitting diodes of each of the plurality of rigid areas.

A size of each of the plurality of glass patterns may be smaller than a size of each of the plurality of rigid areas and the plurality of glass patterns may overlap all the plurality of light emitting diodes.

A size of each of the plurality of glass patterns may be larger than a size of each of the plurality of rigid areas and at least a part of the plurality of glass patterns may overlap the malleable area.

The display device may further include an adhesive layer disposed between the cover window and the display panel, and the resin layer may be disposed so as to cover between the plurality of glass patterns and top surfaces of the plurality of glass patterns and the adhesive layer may be in contact with bottom surfaces of the plurality of glass patterns and a bottom surface of the resin layer.

A top surface of the cover window may be configured by a top surface of the resin layer.

The resin layer may be disposed so as to cover between the plurality of glass patterns and bottom surfaces of the plurality of glass patterns and the display panel may be in contact with the resin layer.

A top surface of the cover window may be configured by top surfaces of the plurality of glass patterns and a top surface of the resin layer.

The plurality of glass patterns may be formed to be narrowed from one surface to an opposite surface of the one surface.

The plurality of glass patterns may be formed to be widened from a top surface to a bottom surface.

The plurality of glass patterns may be formed to be narrowed from a top surface to a bottom surface.

The side surface of each of the plurality of glass patterns may be an uneven surface having a plurality of irregularities.

A width of a top surface of the plurality of glass patterns may be different from a width of a center portion of the plurality of glass patterns.

A width of a bottom surface of the plurality of glass patterns may be different from the width of the center portion of the plurality of glass patterns.

The display device may further include a black resin layer which is disposed along an edge of the cover window on one surface of the cover window, and the black resin layer may be disposed so as to enclose the resin layer.

The black resin layer may her include a plurality of grooves disposed on a bottom surface of the black resin layer.

A part of the resin layer and the black resin layer may be disposed on top surfaces of the plurality of glass patterns and the plurality of grooves may be configured to form a gap between the top surfaces of the plurality of glass patterns and the black resin layer and between the remaining part of the resin layer disposed between the plurality of glass patterns and the black resin layer.

A part of the resin layer and the black resin layer may be disposed below bottom surfaces of the plurality of glass patterns and the plurality of grooves may be configured to form a gap between the display panel and the black resin layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel which includes a plurality of rigid areas and a malleable area, and the malleable area enclosing the plurality of rigid areas; and
a cover window which is disposed on the display panel,
wherein the cover window includes a plurality of glass patterns and a resin layer, and the resin layer covers one side and side surfaces of the plurality of glass patterns,
wherein the plurality of glass patterns overlaps the plurality of rigid areas and the resin layer overlaps the malleable area.

2. The display device according to claim 1, wherein the display panel further includes a plurality of light emitting diodes, each of the plurality of light emitting diodes disposed in each of the plurality of rigid areas and each of the plurality of glass patterns overlaps the plurality of light emitting diodes of each of the plurality of rigid areas.

3. The display device according to claim 2, wherein a size of each of the plurality of glass patterns is smaller than a size of each of the plurality of rigid areas and the plurality of glass patterns overlaps all of the plurality of light emitting diodes.

4. The display device according to claim 2, wherein a size of each of the plurality of glass patterns is larger than a size of each of the plurality of rigid areas and at least a portion of the plurality of glass patterns overlaps the malleable area.

5. The display device according to claim 1, further comprising:
an adhesive layer disposed between the cover window and the display panel,
wherein the resin layer is disposed so as to cover between the plurality of glass patterns and top surfaces of the plurality of glass patterns and the adhesive layer is in contact with bottom surfaces of the plurality of glass patterns and a bottom surface of the resin layer.

6. The display device according to claim 5, wherein a top surface of the cover window is defined by a top surface of the resin layer.

7. The display device according to claim 1, wherein the resin layer is disposed so as to cover between the plurality of glass patterns and bottom surfaces of the plurality of glass patterns and the display panel is in contact with the resin layer.

8. The display device according to claim 7, wherein a top surface of the cover window is defined by top surfaces of the plurality of glass patterns and a top surface of the resin layer.

9. The display device according to claim 1, wherein the plurality of glass patterns has a width that decreases from one surface toward an opposite surface of the one surface.

10. The display device according to claim 1, wherein the plurality of glass patterns has a width that increases from a top surface toward a bottom surface.

11. The display device according to claim 1, wherein the plurality of glass patterns has a width that decreases from a top surface to a bottom surface.

12. The display device according to claim 1, wherein the side surface of each of the plurality of glass patterns is an uneven surface having a plurality of irregularities.

13. The display device according to claim 1, wherein a width of a top surface of the plurality of glass patterns is different from a width of a center portion of the plurality of glass patterns.

14. The display device according to claim 13, wherein a width of a bottom surface of the plurality of glass patterns is different from the width of the center portion of the plurality of glass patterns.

15. The display device according to claim 1, further comprising:
a black resin layer disposed along an edge of the cover window on one surface of the cover window, the black resin layer surrounding the resin layer.

16. The display device according to claim 15, wherein the black resin layer further includes a plurality of grooves disposed on a bottom surface of the black resin layer.

17. The display device according to claim 16, wherein a portion of the resin layer and the black resin layer are disposed on top surfaces of the plurality of glass patterns, and the plurality of grooves define gaps between (i) the top surfaces of the plurality of glass patterns and the black resin layer, and (ii) a remaining portion of the resin layer disposed between the plurality of glass patterns and the black resin layer.

18. The display device according to claim 16, wherein a portion of the resin layer and the black resin layer are disposed below bottom surfaces of the plurality of glass patterns, and the plurality of grooves define a gap between the display panel and the black resin layer.

19. A display device, comprising:
a first substrate having a first area and a second area adjacent to the first area, the first area having a higher modulus of elasticity than the second area;
a cover window disposed on the first substrate, the cover window including:
a glass pattern having at least one surface; and
a resin layer adjacent to the at least one surface of the glass pattern,
wherein the glass pattern overlaps with the first area and the resin layer overlaps with on the second area in a plan view.

20. The display device of claim 19, wherein the resin layer is in direct contact with the at least one surface of the glass pattern.

21. The display device of claim 19, wherein the resin layer further overlaps with the first area in a plan view.

22. The display device of claim 19, further comprising a light emitting diode disposed in the first area;
a filling layer disposed on the light emitting diode; and
a second substrate disposed on the filling layer,
wherein the glass pattern overlaps with the light emitting diode in a plan view.

23. The display device of claim 22, further comprising an adhesive layer disposed on the second substrate,
wherein the adhesive layer is in direct contact with both the glass pattern and the resin layer.

24. The display device of claim 22, wherein the resin layer is in direct contact with the second substrate.

25. The display device of claim 19, wherein the resin layer has greater thickness above the second area than above the first area.

26. The display device of claim 22, wherein the resin layer contacts both the second substrate and the glass pattern without an intermediate adhesive layer.

27. The display device of claim 19, further comprising:
a black resin layer different from the resin layer, the black resin layer disposed along an edge of the cover window surrounding the resin layer; and
grooves defined in the black resin layer along at least one edge of the cover window.
